(19) United States
(12) Patent Application Publication
(10) Pub. No.: US 2006/0240284 A1
(43) Pub. Date: Oct. 26, 2006

(54) Organic electroluminescent device and manufacturing method thereof and flat display device incorporating the same

(76) Inventors: Tswen-Hsin Liu, Jhudong Township (TW); Pei-Chi Wu, Kaohsiung City (TW)

Correspondence Address: RABIN & Berdo, PC, 1101 14TH STREET, NW, SUITE 500, WASHINGTON, DC, 20005, US

(21) Appl. No.: 11/239,393

(22) Filed: Sep. 30, 2005

(30) Foreign Application Priority Data
Apr. 21, 2005 (TW) 94112788

(51) Int. Cl. H01L 51/54; H05B 3/14

(52) U.S. Cl. 428/690; 428/917; 313/504; 313/506; 257/E51.044; 427/66

(57) ABSTRACT

An organic electroluminescent device (OELD) is provided. The OELD includes a substrate, an anode, a cathode, a hole transport layer, a phosphorescent emission layer and a hole blocking layer. The anode and the cathode opposite to the anode are disposed over the substrate. The phosphorescent emission layer is disposed between the anode and the cathode. The phosphorescent emission layer is composed of an octahedral structured emission material. The hole transport layer is disposed between the anode and the phosphorescent emission layer. The hole blocking layer is disposed between the phosphorescent emission layer and the cathode.

This application claims the benefit of Taiwan application Serial No. 94112788, filed Apr. 21, 2005, the subject matter of which is incorporated herein by reference.

### BACKGROUND OF THE INVENTION

1. Field of the Invention

The invention relates in general to an organic electroluminescent device (OELD) incorporating the same and, more particularly, to an organic electroluminescent device consisting of a phosphorescent octahedral-structured emission material and a manufacturing method thereof and a flat display device incorporating the same.

2. Description of the Related Art

Conventional organic electroluminescent device (OELD) is a multi-layer stacked structure and includes a substrate, an anode, a cathode, a hole injection layer, a hole transport layer, an electron transport layer, an electron injection layer and an emission layer. The anode, hole injection layer, the hole transport layer, the emission layer, the electron transport layer, the electron injection layer and the cathode are sequentially disposed on the substrate from bottom to up. The emission layer includes a host and dopant system, that is, the host is mixed with a small amount of dopant. As for how to determine whether the host and dopant system is a fluorescent host and dopant system or a phosphorescent host and dopant system is disclosed below.

When a voltage is applied to the cathode and the anode, the electron will pass through the electron injection layer and the electron transport layer to be injected into the emission layer by the cathode, and the hole will pass through the hole injection layer and the hole transport layer to be injected into the emission layer by the anode. After the electron and the hole are combined in the emission layer, the host will be excited to the excited state from the ground state. Since the host is not stable when at the excited state, the host would return to the ground state from the excited state and transfer energy to the dopant at the same time.

When the dopant receives the energy and is accordingly excited to the excited state from the ground state, the dopant would generate both singlet excitons and triplet excitons. Regardless of the dopant being fluorescent or phosphorescent, the ratio of the probability of forming the triplet exciton to the probability of forming the singlet exciton is approximately 3:1 due to the distribution ratio of the electron spin state.

Both the singlet exciton and the triplet exciton return to the stable ground state by releasing photons, enabling the OELD to be electroluminescent. In the fluorescent host and dopant system, only the light emitted when the singlet exciton returns to the ground state is visible fluorescence. In the phosphorescent host and dopant system, the light emitted when the triplet exciton returns to the ground state is visible phosphorescent, so is the light emitted when the singlet exciton returns to the ground state visible phosphorescent after the conversion of internal system crossing (ISC).

As for the fluorescent host and dopant system, the exciton lifetime for the singlet exciton to return to the ground state from the exciton state is approximately at nanosecond (ns) level, and visible fluorescence will be emitted.

As for the phosphorescent host and dopant system, the exciton lifetime for the triplet exciton to return to the ground state from the exciton state is approximately at microsecond (μs) level, and visible phosphorescent will be emitted. According to the mechanism of OELD, the ratio of the probability of forming the triplet exciton to the probability of forming the singlet exciton is approximately 3:1 due to the distribution of the spinning state of the electron and that the phosphorescent dopant has the feature of converting the singlet energy of the host to the triplet energy, so the internal quantum efficiency of the phosphorescent dopant is approximately four times larger than that of the fluorescent dopant (the theoretic value is 100%). Therefore, the phosphorescent host and dopant system has a better luminance efficiency but a longer exciton lifetime than the fluorescent host and dopant system.

However, the disadvantage of the phosphorescent host and dopant system is that the exciton lifetime is too long. The lifetime of triplet exciton is as high as μs level, which means that the duration that the triplet exciton stays in the emission layer is about 1,000 times than the singlet exciton would stay in the emission layer. The long duration of the triplet exciton in the emission layer would cause triplet-triplet annihilation occurred between the triplet excitons. That is to say, one triplet exciton would collide with another triplet exciton, causing the energy of two triplet excitons to be wasted via heat or vibration instead of being released in the form of photons. Consequently, the luminance efficiency of the OELD, a phosphorescent device for instance, with the phosphorescent host and dopant system will deteriorate dramatically along with the increase in the injected currents, greatly affecting the luminance efficiency of the phosphorescent device. As for the triplet-triplet annihilation encountered in the phosphorescent host and dopant system, refer to the publications such as Baldo, Thompson and Forrest (1999), Appl. Phys. Lett. 75(1), 4-6; R. J. Holmes, S. R. Forrest, and M. E. Thompson et al. (2003), Appl. Phys. Lett. 82(15), 2422.

Besides, the phosphorescent emission layer of conventional OELD still needs the host and dopant system consisting of host and dopant. This is because most of the phosphorescent dopants according to prior art have a planar or a spherical structure, so the molecules are more likely to be stacked and are poor in preventing the concentration quenching effect. The concentration quenching effect is common in the extinction mechanism of the organic dye. The reason is that when the doping concentration of the organic dye is too high, the molecules would be over-stacked and the luminous characteristic would be jeopardized. As a result, the luminance efficiency is deteriorated. Since most molecules of the dopant in phosphorescent emission layer are planar structure, the steric hindrance is insufficient. When the doping concentration of the dopant is too high, the dopant of the phosphorescent emission layer would be over-stacked, resulting in the so called “concentration quenching effect”. Therefore, the method of manufacturing conventional phosphorescent emission layer dopes a small amount of the phosphorescent dopant in a large amount of the host to dilute the concentration of the phosphorescent dopant in the phosphorescent emission layer, hence to reduce the likelihood of the occurrence of the concentration quenching effect. However, complicated co-evaporation technology has to be used to form the abovementioned phosphorescent emission layer, increasing the difficulties during the manufacturing process and the manufacturing cost.

### SUMMARY OF THE INVENTION

It is therefore the object of the present invention to provide an organic electroluminescent device (OELD) and the manufacturing method thereof and a flat display device incorporating the same. The design of using an octahedral-structured emission material to form a phosphorescent emission layer enables the steric hindrance of the emission material of the present invention to outdo the planar structure of conventional phosphorescent dopant. Therefore, the phosphorescent emission layer of the present invention does not need to mix with any other host or dopant, greatly shaking off the restraint imposed by the design of conventional phosphorescent host and dopant system. Consequently, the present invention not only prevents the concentration quenching effect, but also dispenses the complexities and difficulties that would otherwise arise when the complicated co-evaporation manufacturing process is used to form an emission layer with the host and the dopant being mixed together. As a result, the manufacturing process is simplified and the manufacturing cost is further reduced. Moreover, the OELD of the present invention further eliminates the extinction mechanism of triplet annihilation that would easily occur in a conventional phosphorescent device.

According to an object of the present invention, an organic electroluminescent device (OELD) is provided. The OELD includes a substrate, an anode, a cathode, a hole transport layer, a phosphorescent emission layer and a hole blocking layer. The anode and the cathode opposite to the anode are disposed over the substrate. The phosphorescent emission layer is disposed between the anode and the cathode. The phosphorescent emission layer is composed of an octahedral structured emission material. The hole transport layer is disposed between the anode and the phosphorescent emission layer. The hole blocking layer is disposed between the phosphorescent emission layer and the cathode.

According to another object of the present invention, a flat display device is provided. The flat display device incorporating the abovementioned OELD.

According to yet another object of the present invention, a method of manufacturing OELD is provided. At first, a substrate is provided. Next, an anode is formed on the substrate. Then, a hole transport layer is formed on the substrate. A phosphorescent emission layer is formed on the hole transport layer. The phosphorescent emission layer is composed of an octahedral-structured emission material. Next, a hole blocking layer is formed on the phosphorescent emission layer. At last, a cathode opposite to the anode is formed on the hole blocking layer and over the substrate.

The chemical structure of the abovementioned octahedral-structured emission material of the formula [I]:

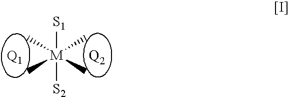

In the above formula, M is a metal atom whose atomic number of the periodic table is greater than 40, Q1 and Q2 are bi-chelate substituents, and S1 and S2 are mono-chelate substituents. Besides, the metal atom (M) is selected from the group consisting of osmium (Os), ruthenium (Ru), iridium (Ir), platinum (Pt), rhenium (Re), thallium (Tl), palladium (Pb), and rhodium (Rh). A transitional metal whose atomic number of the periodic table being greater than 40 is selected as the central atoms, allowing the octahedral-structured emission material to emit visible phosphorescent, Q1 and Q2 can be any bi-chelate substituent, and S1 and S2 can be any mono-chelate substituent.

Other objects, features, and advantages of the present invention will become apparent from the following detailed description of the preferred but non-limiting embodiments. The following description is made with reference to the accompanying drawings.

### BRIEF DESCRIPTION OF THE DRAWINGS

FIG. 1 is a diagram showing a cross-sectional structure of the OELD according to a first embodiment of the present invention;

FIG. 2 is a diagram of rectangular coordinates showing the relationship between the luminance and luminance efficiency of the OELD of FIG. 1;

FIG. 3 is a flowchart of a method of manufacturing the OELD according to a second embodiment of the present invention;

FIG. 4 is a diagram showing a flat display device of the OELD according to a third embodiment of the present invention; and

FIG. 5 is a diagram showing a flat display device of the OELD according to a fourth embodiment of the present invention.

### DETAILED DESCRIPTION OF THE INVENTION

First Embodiment

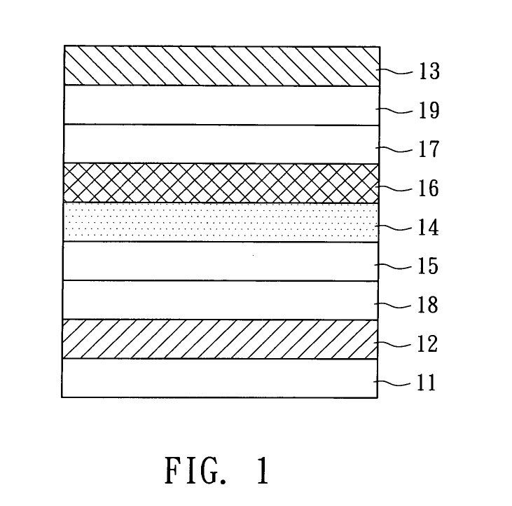

Referring to FIG. 1, a diagram showing a cross-sectional structure of an organic electroluminescent device (OELD) according to a first embodiment of the present invention is shown. In the present embodiment of the invention, the OELD includes a micro-molecular organic light emitting diode (OLED) and a polymer light emitting diode (PLED), is exemplified by an OLED here. However, the technology disclosed in the present embodiment of the invention is also applicable to the PLED.

In FIG. 1, The OELD 10 at least includes a substrate 11, an anode 12, a cathode 13, a phosphorescent emission layer 14, a hole transport layer (HTL) 15 and a hole blocking layer (HBL) 16. The anode 12 is opposite to the cathode 13 and both are disposed over the substrate 11. The cathode 13 is disposed over the anode 12. The phosphorescent emission layer 14 is disposed between the anode 12 and cathode 13 and is composed of an octahedral-structured emission material. As for the chemical structure of the octahedral-structured emission material is disclosed below. When the octahedral structure emission material formed on the phosphorescent emission layer 14 reaches the concentration of 100%, the phosphorescent emission layer 14 is able to emit phosphorescent without using the host and dopant system, greatly shaking off the restraint imposed by the design of conventional phosphorescent host and dopant system.

The hole transport layer 15 is disposed between the anode 12 and phosphorescent emission layer 14. The hole blocking layer 16 is disposed between the phosphorescent emission layer 14 and the cathode 13. Besides, the OELD 10 further includes an electron transport layer (ETL) 17 disposed between the hole blocking layer 16 and the cathode 13. If the hole blocking layer 16 has the function of the abovementioned electron transport layer, the OELD 10 does not necessarily to include the abovementioned electron transport layer 17. Moreover, the OELD 10 further includes a hole injection layer (HIL) 18 and an electron injection layer (EIL) 19. The hole injection layer 18 is disposed between the hole transport layer 15 and the anode 12. The electron injection layer 19 is disposed between the hole blocking layer 16 and the cathode 13. That is, the electron injection layer 19 is disposed between the electron transport layer 17 and the cathode 13.

As for the octahedral-structured emission material is explained by a number of chemical structural formulas. The chemical structure of the abovementioned octahedral-structured emission material of the formula [I]:

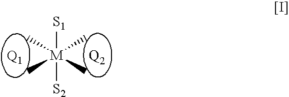

In the above formula, M is a metal atom whose atomic number of the periodic table is greater than 40, allowing the octahedral-structured emission material to emit visible phosphorescent. Q1 and Q2 are two substantially identical or different bi-chelate substituents, while S1 and S2 are two substantially identical or different mono-chelate substituents.

Since Q1 and Q2 are two substantially identical or different bi-chelate substituents, M and Q1 and Q2 construct a quadrilateral plane. Moreover, S and S2 are like a top point and a bottom point of the quadrilateral plane defined by M and Q1 and Q2, so M, Q1, Q2, and S1 and S2 define an octahedral structure. The chemical structure of the octahedral-structured emission material of the present embodiment of the formula [II]:

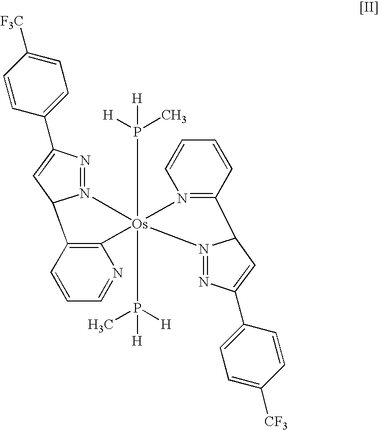

In the present embodiment of the invention, the respective materials of the anode 12, the hole injection layer 18, the hole transport layer 15, the hole blocking layer 16, the electron transport layer 17, the electron injection layer 19 and the cathode 13 are exemplified by indium tin oxide (ITO), copper phthalocyanine (CuPc), 1, 1-bis [N-(1-naphthyl)-N′-phenylamino]biphenyl-4, 4′ diamine (NPB), bis (2-methyl-8-quinolinolato) (p-phenylphenolato) aluminum(BAlq), tris (8-hydroxyquinolinato) aluminum(Alq₃), and composite cathode including lithium fluoride (LiF) and aluminum (Al). The thicknesses of the anode 12, the hole injection layer 18, the hole transport layer 15, the hole blocking layer 16, the electron transport layer 17, the electron injection layer 19 and the cathode 13 are approximately equal to 75 nm (anode), 15 nm (HIL), 60 nm (HTL), 15 nm (HBL), 30 nm (ETL), 1 nm (HIL) and 200 nm (cathode), respectively. Besides, the chemical structure of an octahedral-structured emission material of the phosphorescent emission layer 14 is exemplified by the emission material whose chemical structural of the formula [II]. The thickness of the octahedral-structured emission material of the phosphorescent emission layer 14 can be substantially about 30 nm.

When a voltage is applied to the cathode 13 and the anode 12, the electron will pass through the electron injection layer 19, the electron transport layer 17 and the hole blocking layer 16 to be injected into the phosphorescent emission layer 14 from the cathode 13. The hole will pass through the hole injection layer 18 and the hole transport layer 14 to be injected into the phosphorescent emission layer 14 from the anode 12. After the electron and the hole are combined in the phosphorescent emission layer 14, the octahedral structured emission material such as the material whose chemical structure of the formula [II] would generate both singlet excitons and triplet excitons. The ratio of the probability of forming the singlet exciton to the probability of forming the triplet exciton is approximately 3:1. The triplet exciton of the octahedral emission material would release phosphorescent in the course of returning to the ground state. The singlet exciton would be converted to the triplet exciton via the internal system crossing (ISC) of the octahedral structured emission material such as the material whose chemical structure of the formula [II]. At last, both the singlet and the triplet exciton are released in visible phosphorescent.

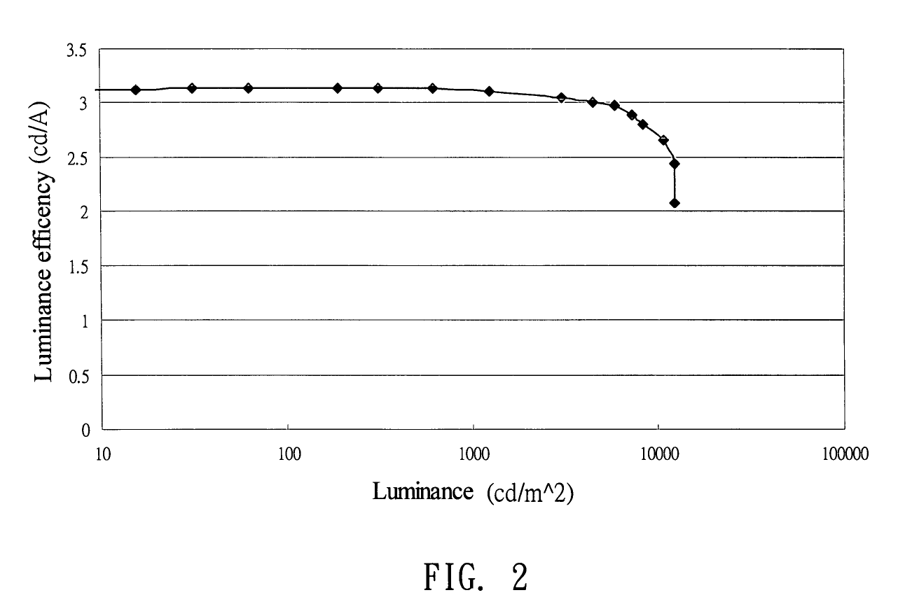

Referring to FIG. 2, a diagram of rectangular coordinates showing the relationship between the luminance and luminance efficiency of the OELD of FIG. 1 is shown. Judging from the relationship between the luminance efficiency and the luminance of FIG. 2, it can be seen that the OELD of the present embodiment of the invention has the luminance efficiency of 3.1 cd/A when at low luminance, and the luminance efficiency will not vary with the increase in operating luminance. When the OELD of the present embodiment of the invention is at high luminance 5,000 (cd/m², nits), the luminance efficiency of the OELD of the present embodiment of the invention still remains above 3.0 cd/A. Compared with conventional phosphorescent device whose luminance efficiency raises and descends dramatically with the change in the operating luminance due to the triplet-triplet annihilation, it is obvious that the OELD of the present embodiment of the invention has effectively eliminated the extinction mechanism of triplet annihilation in the phosphorescent device. Therefore, the present embodiment uses an octahedral structured emission material to form a phosphorescent emission layer, greatly shaking off the restraint imposed by the design of conventional phosphorescent host and dopant system. The luminance efficiency of the OELD of the present embodiment of the invention will not descend dramatically along with the increase in the injected current, greatly enhancing the luminance efficiency of the phosphorescent device.

However, anyone who understands the technology of the present embodiment of invention will realize that the technology of the present embodiment is not limited thereto. For example, the anode 12 and the cathode 13 may include a metal, a metal alloy or a transparent conductive material, and at least one of the anode 12 and the cathode 13 has to be transparent or semi-transparent. The abovementioned transparent conductive material includes indium tin oxide (ITO), indium zinc oxide (IZO), cadmium tin oxide (CTO), stannim dioxide (SnO₂), zinc oxide (ZnO) or other similar transparent metal oxides. The abovementioned metal and metal alloy includes aurum (Au), aluminum (Al), indium (In), magnesium (Mg), calcium (Ca), or the like.

If the cathode 13 can be a reflective metal only when the anode 12 is transparent or semi-transparent, then the OELD 10 is a bottom emission device and the substrate 11 has to be a transparent or a semi-transparent substrate. If the anode 12 can be a reflective metal only when the cathode 13 is transparent or semi-transparent, then the OELD 10 is a top emission device and the substrate 11 can be a transparent, semi-transparent or non-transparent substrate. When the anode 12 and the cathode 13 are transparent or semi-transparent, the OELD 10 is a dual emission device and the substrate 11 has to be a transparent or a semi-transparent substrate.

The M, Q1, Q2, S1 and S2 of the above chemical structural formula [I] are respectively elaborated below. Firstly, the metal atom (M) is selected from the group consisting of osmium (Os), ruthenium (Ru), iridium (Ir), platinum (Pt), rhenium (Re), thallium (Tl), palladium (Pb), and rhodium (Rh).

Despite the octahedral structured emission material of the present embodiment of the invention is exemplified by the material whose chemical structure of the formula [II], the technology of the present embodiment of the invention is not limited thereto. Any emission material, which is luminous, phosphorescent, and octahedral structured, is applicable to the phosphorescent emission layer 14 of the present embodiment of the invention.

The phosphorescent emission layer of 14 of the present embodiment is composed of an octahedral structure emission material, thus having higher steric hindrance than the planar structure of conventional phosphorescent dopant. Therefore, the phosphorescent emission layer 14 of the present embodiment of the invention does not need to mix with any other host or dopant, greatly shaking off the restraint imposed by the design of conventional phosphorescent host and dopant system. Consequently, the present embodiment of the invention not only prevents the concentration quenching effect, but also dispenses the complexities and difficulties that would otherwise arise when the complicated co-evaporation manufacturing process is used to form an emission layer with the host and the dopant being mixed together. As a result, the manufacturing process is simplified and the manufacturing cost is further reduced.

Second Embodiment

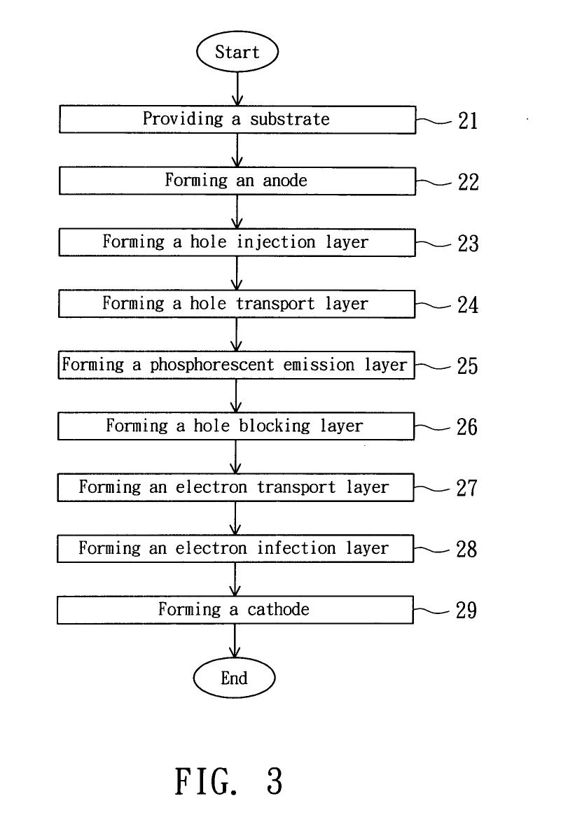

Referring to FIG. 3, a flowchart of the method of manufacturing the OELD according to a second embodiment of the present invention is shown. Referring to FIG. 1 at the same time, the method begins at step 21, a substrate 11 is provided. Next, proceed to step 22, an anode 12 is formed on the substrate 11. Then, proceed to step 23, a hole injection layer 18 is formed on the anode 12. Next, proceed to step 24, a hole transport layer 15 is formed on the hole injection layer 18. Afterwards, proceed to step 25, a phosphorescent emission layer 14 is formed on the hole transport layer 15. The phosphorescent emission layer 14 is composed of an octahedral-structured emission material. The octahedral-structured emission material formed on the phosphorescent emission layer 14 reaches the concentration of 100%, the phosphorescent emission layer 14 is able to emit phosphoresce without using the host and dopant system, greatly shaking off the restraint imposed by the design of conventional phosphorescent host and dopant system.

Next, proceed to step 26, a hole blocking layer 16 is formed on the phosphorescent emission layer 14. Then, proceed to step 27, an electron transport layer 17 is formed on the hole blocking layer 16. Afterwards, proceed to step 28, an electron injection layer 19 is formed on the electron transport layer 17. At last, a cathode 13 opposite to the anode 12 is formed on the electron injection layer 19 and over the substrate 11, and an OELD 10 is formed.

The chemical structure of the abovementioned octahedral-structured emission material of formula [I]:

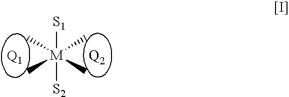

In the above formula, M is a metal atom whose atomic number of the periodic table is greater than 40, allowing the octahedral-structured emission material to emit visible phosphorescent. Q1 and Q2 are two substantially identical or different bi-chelate substituents, while S1 and S2 are two substantially identical or different mono-chelate substituents. Besides, the metal atom (M) is selected from the group consisting of osmium (Os), ruthenium (Ru), iridium (Ir), platinum (Pt), rhenium (Re), thallium (Tl), palladium (Pb), and rhodium (Rh). The chemical structure of the octahedral-structured emission material of the present embodiment of formula [II]:

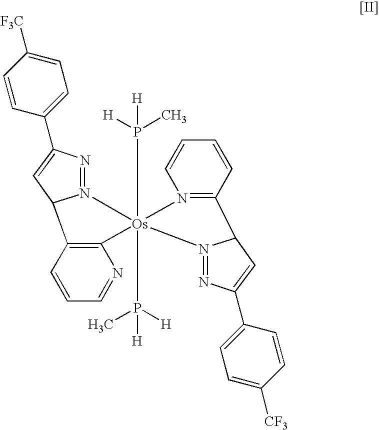

However, anyone who is skilled in the technology of the present embodiment will realize that the technology of the present embodiment is not limited thereto. For example, if the hole blocking layer also has the function of the abovementioned electron transport layer, the abovementioned step 27 of forming an electron transport layer on the hole blocking layer 16 can be omitted.

Third Embodiment

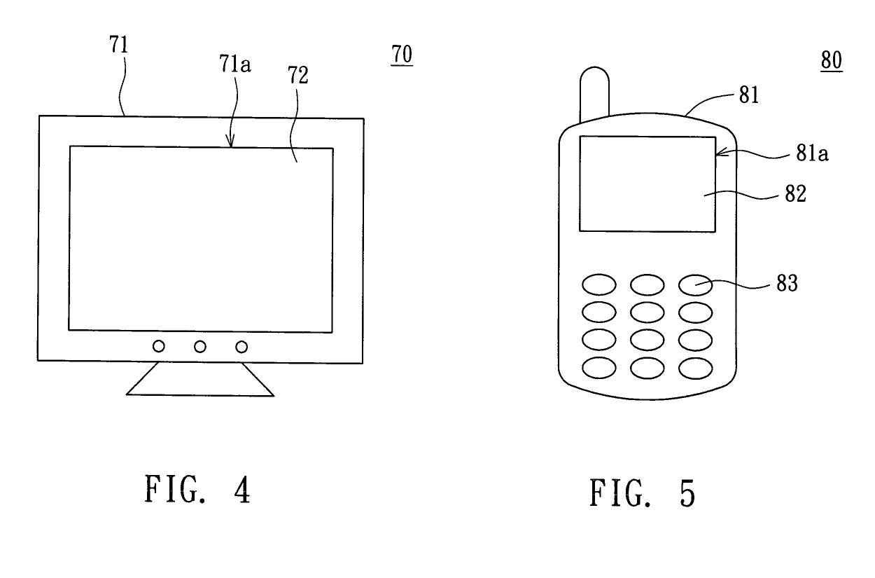

Referring to FIG. 4, a diagram showing a flat display device of the OELD according to a third embodiment of the present invention is shown. In FIG. 4, a flat display device 70 can be a flat monitor such as a computer screen, a flat TV or a monitor screen. In the present embodiment of the invention, the flat display device 70 is exemplified by a computer screen.

In FIG. 4, the flat display device 70 includes a housing 71 and a display panel 72. The display panel 72 is disposed in the housing 71 and at least includes the abovementioned OELD 10. Besides, the display region of the display panel 72 is exposed outside via the front opening 71a of the housing 71.

Fourth Embodiment

Referring to FIG. 5, a diagram showing a flat display device of the OELD according to a fourth embodiment of the present invention is shown. In FIG. 5, the flat display device can be a mobile display device 80, such as mobile phone, handheld computer, handheld game station, digital camera (DC), digital video device (DVD), digital audio device, personal digital assistant (PDA), notebook, table PC, and so forth. In the present embodiment, the mobile display device 80 is exemplified by a mobile phone.

In FIG. 5, the mobile display device 80 includes a housing 81, a display panel 82 and a keypad 83. The display panel 82 is disposed in the housing 81 and at least includes the abovementioned OELD 10. Besides, the display region of the display panel 82 is exposed outside via the front opening 81a of the housing 81. The keypad 83 is disposed on the front side of the housing 81 and positioned on one side of the display panel 82.

Besides, the OELD 10 of the present embodiment of the invention can be applied to any electronic device with a display panel disposed therein.

An organic electroluminescent device and the manufacturing method thereof and the flat display device incorporating the same are disclosed in the above embodiments of the invention. The design of using an octahedral-structured emission material to form a phosphorescent emission layer enables the steric hindrance of the emission material of the present embodiment of the invention to outdo the planar structure of conventional phosphorescent dopant. Therefore, the phosphorescent emission layer of the present embodiment of the invention does not need to mix with any other host or dopant, greatly shaking off the restraint imposed by the design of conventional phosphorescent host and dopant system. Consequently, the invention not only prevents the concentration quenching effect, but also dispenses the complexities and difficulties that would otherwise arise when the complicated co-evaporation manufacturing process is used to form an emission layer with the host and the dopant being mixed together. As a result, the manufacturing process is simplified and the manufacturing cost is further reduced. Moreover, the OELD of the invention further eliminates the extinction mechanism of triplet annihilation that would easily occur in a conventional phosphorescent device.

While the invention has been described by way of example and in terms of a preferred embodiment, it is to be understood that the present invention is not limited thereto. On the contrary, it is intended to cover various modifications and similar arrangements and procedures, and the scope of the appended claims therefore should be accorded the broadest interpretation so. as to encompass all such modifications and similar arrangements and procedures.

We claim:

1. An organic electroluminescent device (OELD), comprising:
a substrate;
an anode and a cathode opposite to the anode disposed over the substrate;
a phosphorescent emission layer disposed between the anode and the cathode, wherein the phosphorescent emission layer is composed of an octahedral-structured emission material;
a hole transport layer disposed between the anode and the phosphorescent emission layer; and
a hole blocking layer disposed between the phosphorescent emission layer and the cathode.

2. The OELD of claim 1, further comprising:
an electron transport layer disposed between the hole blocking layer and the cathode.

3. The OELD of claim 1, further comprising:
a hole injection layer disposed between the hole transport layer and the anode; and
an electron injection layer disposed between the hole blocking layer and the cathode.

4. The OELD of claim 1, wherein the chemical structure of the octahedral-structured emission material of the formula [I]: 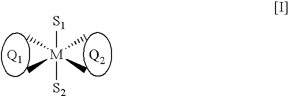
wherein M is a metal atom whose atomic number of the periodic table is greater than 40, Q1 and Q2 are bi-chelate substituents, S1 and S2 are mono-chelate substituents.

5. The OELD of claim 4, wherein the metal atom (M) is selected from the group consisting of osmium (Os), ruthenium (Ru), iridium (Ir), platinum (Pt), rhenium (Re), thallium (Tl), palladium (Pb), and rhodium (Rh).

6. A flat display device incorporating the OELD of claim 1.

7. A method of manufacturing organic electroluminescent device (OELD), comprising:
providing a substrate;
forming an anode and a cathode opposite to the anode over the substrate;
forming a phosphorescent emission layer between the anode and the cathode, wherein the phosphorescent emission layer is composed of an octahedral-structured emission material;
forming a hole transport layer between the anode and the phosphorescent emission layer; and
forming a hole blocking layer between the phosphorescent emission layer and the cathode.

8. The method of claim 7, further comprising:
forming an electron transport layer between the hole blocking layer and the cathode.

9. The method of claim 7, further comprising:
forming a hole injection layer between the hole transport layer and the anode; and
forming an electron injection layer between the hole blocking layer and the cathode.

10. The method of claim 7, wherein the chemical structure of the octahedral-structured emission material of the formula [I]: 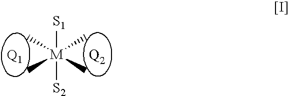
wherein M is a metal atom whose atomic number of the periodic table is greater than 40, Q1 and Q2 are bi-chelate substituents, S1 and S2 are mono-chelate substituents.

11. The method of claim 10, wherein the metal atom (M) is selected from the group consisting of osmium (Os), ruthenium (Ru), iridium (Ir), platinum (Pt), rhenium (Re), thallium (Tl), palladium (Pb), and rhodium (Rh).
